(19) United States
(12) Patent Application Publication
(10) Pub. No.: US 2010/0219453 A1
(43) Pub. Date: Sep. 2, 2010

(54) Nanotube Device

(75) Inventors: Risto Kaunisto, Espoo (FI); Jari Kinaret, Molndal (SE); Eleanor Campbell, Molndal (SE); Andreas Isacsson, Molndal (SE); Sang-Wook Lee, Goterborg (SE); Anders Eriksson, Goteborg (SE)

Correspondence Address: HARRINGTON & SMITH, 4 RESEARCH DRIVE, Suite 202, SHELTON, CT, 06484-6212, US

(73) Assignee: Nokia Corporation, Espoo (FI)

(21) Appl. No.: 12/682,797

(22) PCT Filed: Oct. 15, 2007
(86) PCT No.: PCT/EP2007/060983

§ 371 Date: Apr. 13, 2010

(51) Int. Cl. H01L 29/40; H01L 21/71

(52) U.S. Cl. 257/213; 438/666; 977/742; 438/680; 257/E21.536; 257/E29.111

(57) ABSTRACT

A device includes a nanotube source electrode located on a surface of a substrate between nanotube gate and nanotube drain electrodes.

### FIELD OF THE INVENTION

The invention relates to a device including a nanotube electrode, and to a method of making such a device.

### BACKGROUND TO THE INVENTION

Nanotube devices are known for use is various electrical applications. Since their operation depends on mechanical movement, nanotube devices can be termed NanoElectroMechanical (NEMS) structures.

WO 2005/112126 describes a device which can serve as a multi-state logical switch or as a memory element. WO 03/078305 describes a similar carbon nanotube device which can be used as a filter.

### SUMMARY OF THE INVENTION

A first aspect of the invention provides a device comprising a nanotube source electrode located on a surface of a substrate between nanotube gate and nanotube drain electrodes.

A device thus constructed can suffer less from parasitic capacitance between the gate and drain electrodes than the prior art. This in turn can reduce leakage currents.

The nanotube source electrode may comprise one or more nanotubes extending generally perpendicularly to the surface of the substrate. This can allow the lengths of the nanotube components to be better controlled or, put another way, can allow the lengths of the nanotube components to be better predicted. When using a chemical vapour deposition process to produce nanotubes, the length of the nanotubes is a function of synthesising duration. The vertical placement also can allow for tuning of frequency and actuation force separately from one another. This is advantageous since it can maintain a relatively wide tuning range, compared to the prior art.

The nanotube source electrode may comprise an array of plural nanotubes. This can allow the capacitance between the nanotubes forming part of the nanotube electrode and the gate and drain electrodes to be increased, providing improved device performance and quality compared to the prior art. Also, this can allow the use of fabrication techniques which allow the geometry of the device to be relatively precisely defined, compared to the prior art lift-off/wet etching fabrication techniques. It can be said that using this invention can result in superior fabrication control and reliability.

The array may be a one dimensional array. A one dimensional array gives more controllable oscillation properties and a lower actuation force requirement than does a two dimensional array. The array may alternatively be a two dimensional array.

The nanotubes of the gate and drain electrodes may extend generally perpendicularly to the surface of the substrate. This can allow electrostatic interaction with the nanotube electrode for an increased distance, compared to the prior art. In particular, with this arrangement electrostatic interaction can be provided for the whole of the length of the nanotubes, not just a portion as with the prior art. This can provide increased output power, possibly of several orders of magnitude higher than is possible with the prior art. The use of vertical structures (i.e. structures which are perpendicular to the substrate) also can allow large arrays more easily to be fabricated. Optionally, each of the gate and drain electrodes comprises an array of plural nanotubes. This can provide an advantageous increase in the effective capacitance area. This, in turn, can provide increased output power, possibly of several orders of magnitude higher than is possible with the prior art. Also, this can allow the use of fabrication techniques which allow the geometry of the device to be relatively precisely defined, compared to the prior art lift-off/wet etching fabrication techniques.

Some or all of the nanotubes may be electroplated. This improves the electrical properties and structural rigidity of the nanotubes.

The invention also provides a filter, for instance a radio frequency tunable filter, comprising a device as recited above.

The invention also provides a voltage-controlled oscillator comprising a device as recited above.

A second aspect of the invention provides a method of making a device, the method comprising:
providing a substrate;
providing gate, source and drain electrodes on the substrate, the source electrode being located between the gate and drain electrodes; and
providing each of the source gate and drain electrodes with one or more nanotubes.

Providing the nanotubes may comprise seeding the electrode with a catalyst.

Providing the nanotubes may comprise growing the nanotubes using chemical vapour deposition.

The method may comprise electroplating the nanotubes of the gate and drain electrodes.

### EMBODIMENTS OF THE INVENTION

Embodiments of the present invention will now be described, by way of example only, with reference to the accompanying drawings, in which:

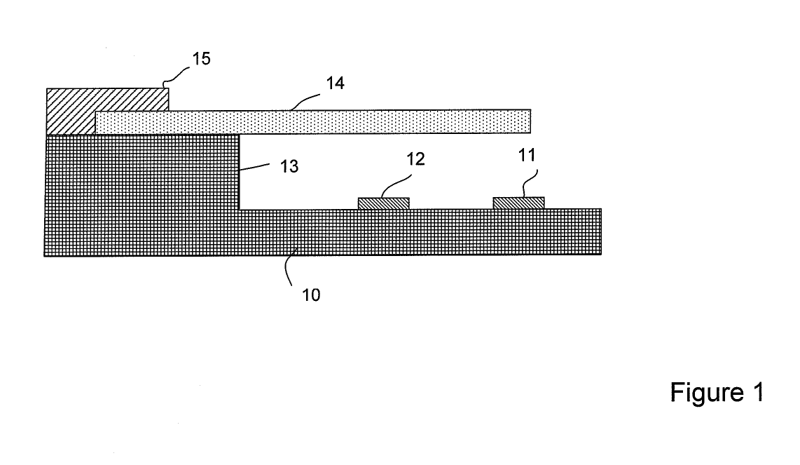

FIG. 1 is a schematic diagram of a known type of nanotube device;

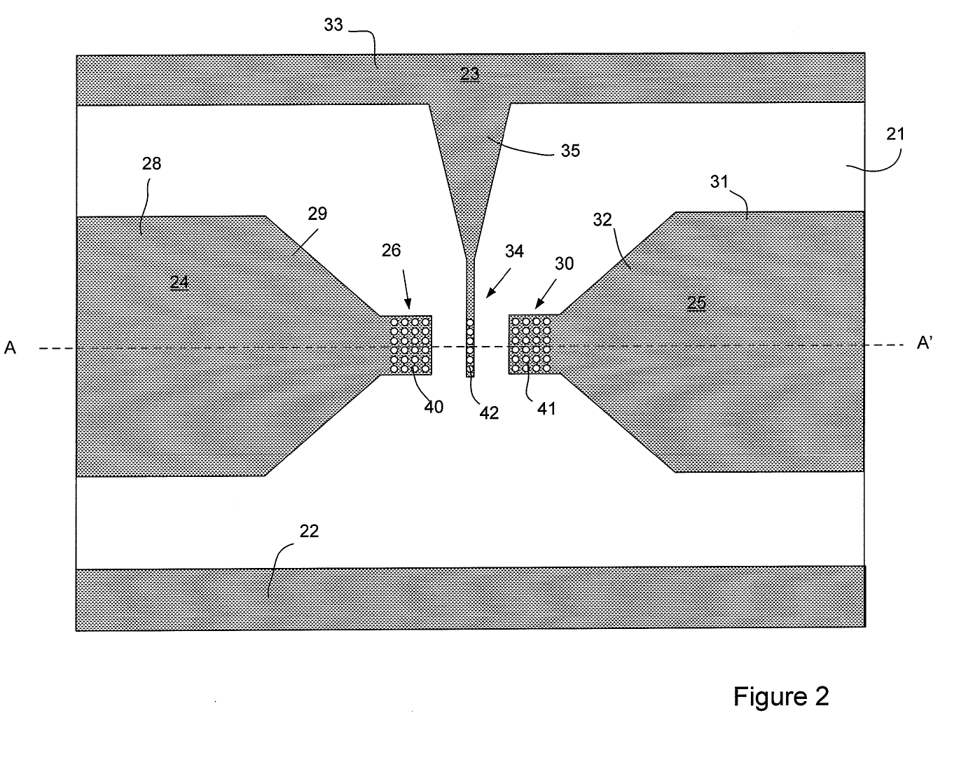

FIG. 2 is a schematic plan view of a device according to the present invention;

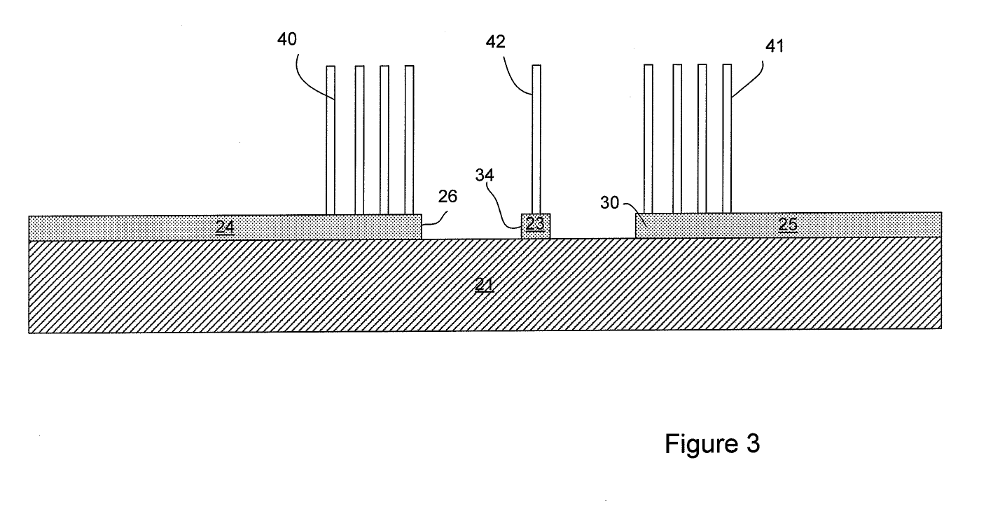

FIG. 3 is a section through a line A-A′ in FIG. 2;

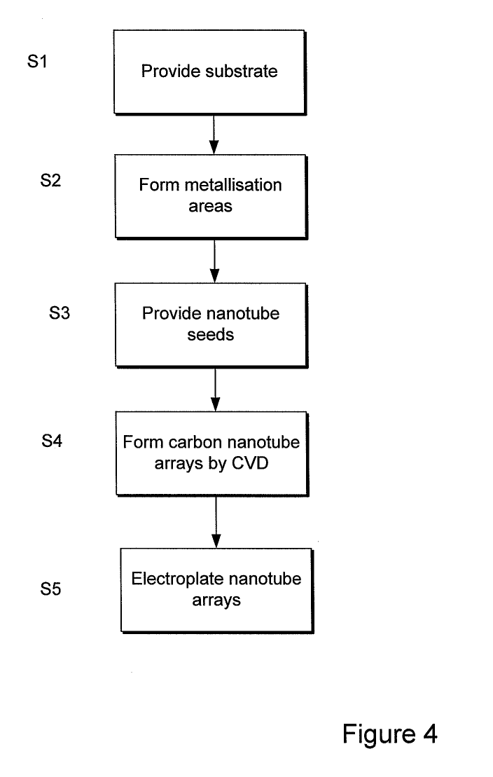

FIG. 4 is a flow chart illustrating a method of producing the FIGS. 2 and 3 device;

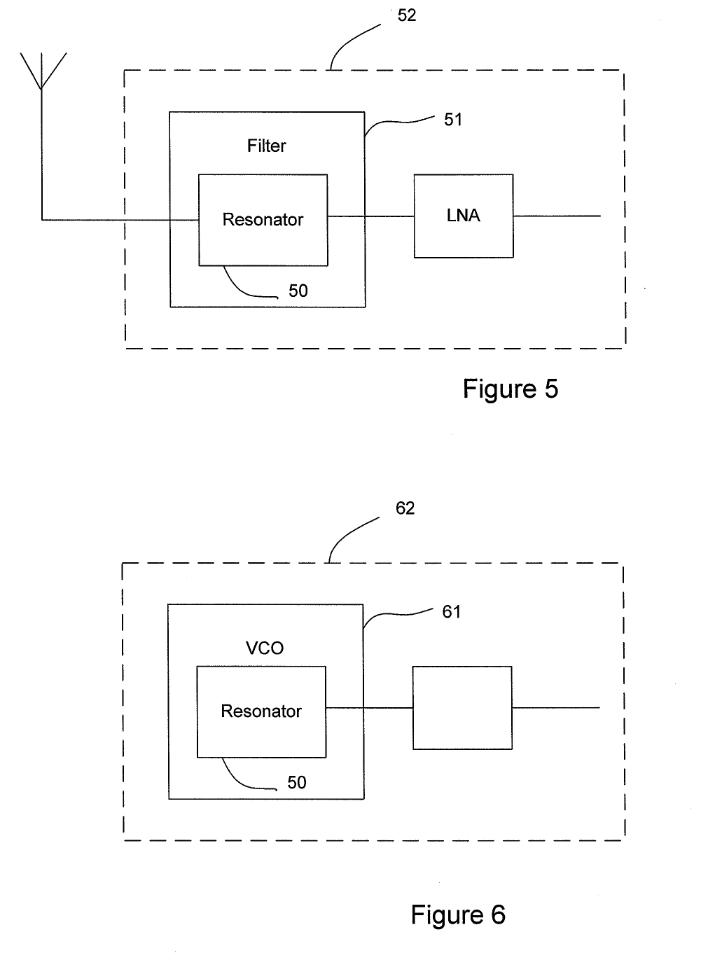

FIG. 5 is a diagram illustrating a radio receiver incorporating the FIGS. 2 and 3 device; and

FIG. 6 is a diagram illustrating an alternative radio receiver incorporating the FIGS. 2 and 3 device.

FIG. 1 shows a nanotube device of the type described in WO 2005/112126 and WO 03/078305. The device comprises a substrate 10, on which are formed a drain electrode 11, a gate electrode 12 and a support 13. The support 13 has a relatively tall profile.

Formed on an uppermost surface of the support 13 is a carbon nanotube 14 and a source electrode 15, which are in mechanical and electrical contact with one another. The carbon nanotube 14 extends parallel to the substrate 10 and thus can be described as being horizontal. The carbon nanotube 14 extends above the drain and gate electrodes 11, 12. The carbon nanotube 14 is separated from the drain and gate electrodes 11, 12 by a distance approximately equal to the difference between the heights of the drain and gate electrodes 11, 12 and the height of the support 13. The carbon nanotube 14 is mounted as a supported cantilever above the gate and drain electrodes 11, 12. A time-varying voltage applied to the gate electrode 12 causes deflection of the carbon nanotube 14 in a direction perpendicular to the plane of the substrate 21.

FIG. 1 is a simplified diagram of the device structure. For more details of the structure and its operation, reference should be made to the two documents mentioned above.

The inventors are aware that several problems exist with the horizontal structure shown in FIG. 1. In particular, the inventors are aware that the parasitic capacitance between the gate and source electrodes 12, 13 typically is dominant. This results in part because the capacitance between the carbon nanotube 14 and the drain electrode 11 and the gate electrode 12 can be very small and in part because the parasitic capacitance between the gate and source electrodes 12, 13 can be quite large. As a consequence of these two effects, the signal mediated between the gate and drain electrodes 11, 12 can be comparable to the direct leakage signal between the source and drain electrodes 13, 14. Furthermore, since both mechanical actuation and transduction depend on capacitive coupling between the carbon nanotube 14 and the gate and drain electrodes 11, 12, the mechanical actuation and transduction can be relatively weak.

It is desirable to reduce the parasitic capacitance whilst at the same time increasing the actuating capacitances between the gate and drain electrodes 11, 12 and the carbon nanotube 14. Increasing the actuating capacitance is important since the output power of the device is proportional to the product of the characteristic RC-time and the working frequency.

Also, the device shown in FIG. 1 can be relatively difficult to fabricate. Fabrication problems result from it being difficult to control the length and alignment of the carbon nanotube 14. This can make large scale integration and creation of uniform arrays of devices difficult and thus expensive.

FIG. 2 is a plan view of a device 20 constructed in accordance with the present invention. The device 20 includes a number of components formed on a substrate 21. Four separate metallized electrodes are formed on the substrate 21. These electrodes are formed by a ground metallisation area 22, a source metallisation area 23, a gate metallisation area 24 and a drain metallisation area 25.

The ground metallisation area 22 is shown as a rectangular strip at the lower most part of the Figure.

The gate metallisation area 24 comprises three main portions. These include a rectangular portion 26 located towards a central part of the device 20. The rectangular portion 26 is relatively small in size. It is connected to a larger rectangular portion 28 which is located distant from the centre of the device 20. The two rectangular portions 26, 28 are connected together by a tapered portion 29. The gate metallisation area 24 is generally symmetrical about a line A-A′ which intersects all three of the portions 26, 28, 29.

On the opposite side of the device 20, the drain metallisation area 25 has the same shape as the gate metallisation area 24, although it is a mirror image thereof. Thus, the drain metallisation area 25 includes a relatively small rectangular portion 30 which is located towards the centre of the device 20, a larger rectangular portion 31 located towards the edge of the device 20, and a tapered portion 32 which connects the two rectangular portions 30, 31.

The source metallisation area 23 includes three main portions. A first is a large rectangular portion 33, which extends along an edge of the device 20 and is generally opposite the ground metallisation area 22. The source metallisation area 23 also includes a narrow rectangular portion 34. One end of the source metallisation area 23 is interposed directly inbetween the small rectangular portions 26, 30 of the gate and drain metallisation areas 24, 25. A longitudinal axis of the narrow rectangular portion 34 of the source metallisation area 33 extends perpendicularly to the line A-A′ which intersects the gate and drain metallisation portions 24 and 25 along their central axis. The narrow rectangular portion 34 is connected to the larger rectangular portion 33 by a tapered portion 35.

The smaller rectangular portions 26, 30 and 34 of the gate, drain and source metallisation areas respectively comprise active electrode regions. In particular, as will now be described, carbon nanotubes are formed on the small rectangular portions 26, 30, 34 extending perpendicularly from the plane of the substrate 21. The carbon nanotubes are shown in FIG. 2 but are best viewed in FIG. 3, which is a section taken along the line A-A′ in FIG. 2.

Referring to FIG. 3, the gate, drain and source metallisation areas 24, 25 and 23 are shown on top of the substrate 21. A first array 40 of carbon nanotubes is formed on the small rectangular portion 26 of the gate metallisation area 24. The first array 40 comprises twenty-four carbon nanotubes arranged in a regular grid of six carbon nanotubes by four carbon nanotubes. As can be seen in FIG. 2, the first array 40 of carbon nanotubes is four deep in the direction of the line A-A′ and six deep in the direction which is perpendicular to the page in FIG. 3.

A second carbon nanotube array 41 has the same arrangement and is formed on the small rectangular portion 30 of the drain metallisation area 25.

A third array 42 of carbon nanotubes is formed on the small rectangular portion 34 of the source metallisation area 23. The third carbon nanotube array 42 is a one dimensional array. It comprises a single row of six carbon nanotubes.

The first, second and third carbon nanotube arrays 40, 41 and 42 are substantially in alignment with one another. The third carbon nanotube array 42 is directly between the first and second carbon nanotube arrays 40, 41. Furthermore, the first and third carbon nanotube arrays 40, 42 are separated from one another by a distance approximately equal to the distance between the second and third carbon nanotube arrays 41, 42.

The first and second carbon nanotube arrays 40 and 41 are electroplated. Electroplating increases the conductivity of the nanotubes. It also increases the structural rigidity of the carbon nanotube arrays 40 and 41.

Only the drain and gate nanotube electrode arrays 40, 41 are metallized by electroplating. Electroplating increases their conductivity and rigidity. The third, gate nanotube electrode array 42 is not metallized. This maintains its desirable mechanical oscillation capabilities.

Electroplating the drain and gate nanotube electrode arrays 40, 41 may or may not fix the nanotube arrays together; depending to some degree on the separation of individual nanotubes in the array. in any case, the drain and gate nanotube electrode arrays 40, 41 will be mechanically stiff after electroplating.

A method of making the device will now be described with reference to FIG. 4.

The first step, Step S1, is to provide the substrate 21. At Step S2, the metallisation areas 22 to 24 are formed on the substrate 21. This can be carried out in any suitable manner. This step provides gate, source and drain electrodes on the substrate. The source electrode is located between the gate and drain electrodes. At Step S3, seeds for the nanotubes are provided at the relevant locations on the metallisation areas 23 to 25. The seeds are catalyst particles. Good catalyst particles are Iron (Fe) particles, although other seeds may also be suitable. At Step S4, the carbon nanotube arrays 40 to 42 are formed from the seeds using chemical vapour deposition (CVD). In Step S5, the carbon nanotubes are electroplated. This can be carried out in any suitable manner. Any suitable material may be used for the electroplating layer on the carbon nanotubes. For instance, the nanotubes may be electroplated with silver (Ag) or copper (Cu).

Since the cantilever (i.e. the third array 42 of nanotubes) and the electrodes (i.e. the first and second arrays 40, 41 of nanotubes) are grown at the same time, in the same step, the fabrication process can be simpler in the sense that there are fewer fabrication steps than in the prior art referred to above. Growing the cantilever and the electrodes at the same time also simplifies the process of getting the electrodes and cantilever to be of sufficiently similar heights.

By growing the nanotubes of the third array 42 from appropriate catalyst particles, such as Iron (Fe), it can be possible to contact many shells simultaneously to the source electrode 23, thereby decreasing contact resistance between the third array 42 of nanotubes and the source metallisation area 23.

Operation of the device 20 will now be described. In the following, the gate and drain electrodes 24, 25 are considered to include the first and second nanotube arrays 40, 41 respectively.

In operation, the gate and drain electrodes 24, 25 are biased by fixed DC-voltages V_{G} and V_{D} respectively. These biases determine the working point of the device 20. The reasons for this can be understood by considering the electrostatic force exerted on the nanotubes of the third array 42 at fixed DC biases. Each of the junctions between the nanotubes of the third array 42 and the electrodes can be modelled by capacitances C_{G}(x) and C_{D}(x) respectively, where x is the displacement of the tip of a carbon nanotube of the third array 42 from the equilibrium position towards the drain electrode 25. The bias voltages give rise to an electrostatic force on the nanotubes of the third array 42 given by the equation:

F_{electric}˜V_{G}²C_{G}′(x)+V_{D}²C_{D}′(x).

Balancing this force with the elastic force, a static bending of the nanotubes of the third array 42 is achieved resulting in a working point x₀:

F_{electric}(x₀)+F_{elastic}(x₀)=0.

If, at certain biases, an AC-signal δV_{G}(t) is superposed on the gate electrode 24, an additional time varying force is present and for small vibrations around the stationary equilibrium x₀ the total time varying force is given by:

F=[V_{G}+δV_{G}(t)]²C_{G}′(x)+V_{D}²C_{D}′(x)+F_{elastic}(x)˜2V_{G}δV_{G}(t)C_{G}′(x₀)+δ(V_{G},V_{D})[x−x₀]

In this equation, a renormalized spring constant δ results from linearization around the working point x₀. Whilst similar to the actuating force in the prior art horizontal arrangement, this equation has an important feature. In particular, since the actuating force is proportional to V_{G} and the renormalized elastic constant δ(V_{G}, V_{D}) depends on both V_{G} and V_{D} the amplification of the electrostatic force and the working point can be controlled independently. This means that the full frequency tuning range is available without changing the actuating force.

The output signal on the drain is proportional to the displacement current generated by the time varying capacitance and is given roughly by the time derivative of the instantaneous charge on the drain capacitor as follows:

I_{drain}˜d/dt[V_{D}C_{D}(x(t))]

Thus, as long as the applied AC signal is off resonance at the working point, the carbon nanotube does not oscillate and there is no significant output current. If the AC signal is on resonance, nanotube oscillations appear and an AC current on the drain is obtained.

There are benefits from having both the actuating force and the output current depend on the magnitude of the capacitances. Firstly, by having the gates of the same height as the nanotube these capacitance can be increased by an order of magnitude as compared to the horizontal structure described in the prior art. Secondly, the vertical structures allow plural nanotubes to be placed between the gate and drain electrodes. Capacitance is increased linearly with the length of the array.

Various variations to the above devices 20 may be made. For instance, the source electrode 23 may include only a single nanotube or a very large number, e.g. of the order of thousands, of nanotubes.

The device 20 can be used as resonator in an electrical filter. This is shown in FIG. 5. The filter can be tuned by varying the bias voltages applied to the gate and drain electrodes 24, 25, as will be appreciated from the above explanation.

As shown in FIG. 5, the resonator 50, which comprises the device 20 and controllable voltage bias circuitry (not shown) is included as part of filter 51 of an RF front end of a radio receiver, in this example a radio transceiver 52.

A filter incorporating the device 20 can also be used in a front end of RF transmitter, that is, between the power amplifier and the antenna.

By using the device 20 in the resonator 50, the resonator 50 can be a high quality, or high-Q, resonator. Furthermore, because of its structure, it is highly miniature. It is particularly advantageous compared to known resonators in that it has low-voltage tuning capabilities. These capabilities derive from the physical arrangement of the device 20, as shown in FIGS. 2 and 3. The resonator 50 is suitable for forming an essential component in software-defined and cognitive radio hardware.

The device 20 has a number of other potential applications.

For instance, the device can also be used as a resonator in a voltage-controlled oscillator (VCO). This is shown in FIG. 6. This kind of VCO is an integral part of a radio synthesizer. The potentially wide tuning range and high quality factor of the resonator device of the invention enable low phase noise synthesizers operating at several RF bands with only a single core VCO.

The VCO can be tuned by varying the bias voltages applied to the gate and drain electrodes 24, 25, as will be appreciated from the above explanation.

As shown in FIG. 6, the resonator 50, which comprises the device 20 and controllable voltage bias circuitry (not shown) is included as part of VCO 61 of a radio receiver, in this example a radio transceiver 62.

1. A device comprising a nanotube source electrode located on a surface of a substrate between nanotube gate and nanotube drain electrodes wherein some or all of the nanotubes of the nanotube gate and nanotube drain electrodes are rigid.

2. A device as claimed in claim 1, wherein the source electrode comprises one or more nanotubes extending generally perpendicularly to the surface of the substrate.

3. A device as claimed in claim 1, wherein the source electrode comprises an array of plural nanotubes.

4. A device as claimed in claim 3, wherein the array is a one dimensional array.

5. A device as claimed in claim 1, wherein the nanotubes of the gate and drain electrodes extend generally perpendicularly to the surface of the substrate.

6. A device as claimed in claim 5, wherein each of the gate and drain electrodes comprises an array of plural nanotubes.

7. A device as claimed in claim 1, wherein some or all of the nanotubes are electroplated.

8. A filter comprising a device as claimed in claim 1.

9. A radio frequency tunable filter comprising a device as claimed in any claim 1.

10. A voltage controlled oscillator comprising a device as claimed in claim 1.

11. A method of making a device, the method comprising:
providing a substrate;
providing gate, source and drain electrodes on the substrate, the source electrode being located between the gate and drain electrodes; and
providing each of the source, gate and drain electrodes with one or more nanotubes,
wherein the one or more nanotubes of either or both of the gate and drain electrodes are rigid.

12. A method as claimed in claim 11, wherein providing the nanotubes comprises seeding the electrode with a catalyst.

13. A method as claimed in claim 12, wherein providing the nanotubes comprises growing the nanotubes using chemical vapour deposition.

14. A method as claimed in claim 11, comprising electroplating the nanotubes of the gate and drain electrodes.
